(19) United States
(12) Patent Application Publication
(10) Pub. No.: US 2001/0013313 A1
(43) Pub. Date: Aug. 16, 2001

(54) Apparatus for fabricating semiconductor structures and method of forming the structures

(75) Inventors: Ravindranath Droopad, Chandler, AZ (US); Zhiyi Yu, Gilbert, AZ (US); William J. Ooms, Prescott, AZ (US); Jamal Ramdani, Chandler, AZ (US)

Correspondence Address: Motorola Inc, Intellectual Property Section, Corporate Law Department, Suite R3163 P O Box 10219, Scottsdale, AZ, 85271-0219, US

(73) Assignee: Motorola, Inc.

(21) Appl. No.: 09/780,119

(22) Filed: Feb. 9, 2001

Related U.S. Application Data
(63) Continuation-in-part of application No. 09/607,207, filed on Jun. 28, 2000.
Application No. 09/607,207 is a continuation-in-part of application No. 09/502,023, filed on Feb. 10, 2000.

(51) Int. Cl. C30B 35/00; H01L 29/04; H01L 31/036

(52) U.S. Cl. 117/200; 257/49

(57) ABSTRACT

An apparatus (100) and method (800) for forming high quality epitaxial layers of monocrystalline materials grown overlying monocrystalline substrates (310) such as large silicon wafers is provided. The apparatus (100) includes at least two deposition chambers (110) and (140) that are coupled together. The first chamber (110) is used to form an accommodating buffer layer (320) on the substrate (310) and the second (140) is used to form a layer of monocrystalline material (330) overlying the accommodating buffer layer (320).

### CROSS REFERENCE TO RELATED APPLICATIONS

This application is a continuation-in-part of application Ser. No. 09/607,207, entitled Semiconductor Structure, Semiconductor Device, Communicating Device, Integrated Circuit, and Process for Fabricating the Same, filed Jun. 28, 2000, which is a continuation-in-part of application Ser. No. 09/502,023, filed Feb. 10, 2000.

### FIELD OF THE INVENTION

This invention relates generally to an apparatus for forming semiconductor structures having multiple epitaxial layers and to a method for their fabrication, and more specifically to multi-chamber deposition equipment configured to form the structures and a method of using the equipment to form the structures.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

Furthermore, the attempts to grow the monocrystalline films on a substrate often include forming multiple monocrystalline layers using separate, dedicated deposition reactors. For example, if a structure includes a first monocrystalline layer of a first type formed over a substrate and a second monocrystalline layer of a second type formed over the first monocrystalline layer, a first reactor is typically used to form the first layer and a second reactor is used to form the second layer.

The use of separate reactors to form the various monocrystalline layers is problematic for several reasons. In particular, the vacuum pressure attained for purposes of monocrystalline layer formation must be vented to ambient conditions to transport the substrates from one reactor to the next. When the substrates are exposed to the ambient conditions, the substrates are exposed to contaminants such as carbon, carbon dioxide, water vapor, and other oxidants present in the atmosphere. The contaminants and/or undesired oxidation may require additional processing to remove the material and/or may deleteriously affect properties such as electron transport and optical efficiency in subsequently grown films.

Accordingly, a need exists for semiconductor structure manufacturing equipment that provides multiple chambers for forming multiple monocrystalline films on a single substrate, without exposing the substrate to ambient conditions when transferring the substrates between reactors.

### BRIEF DESCRIPTION OF THE DRAWINGS

The present invention is illustrated by way of example and not limitation in the accompanying figures, in which like references indicate similar elements, and in which:

FIG. 1 illustrates schematically an apparatus for fabricating semiconductor structures in accordance with the present invention;

FIG. 2 illustrates schematically an apparatus for fabricating semiconductor structures in accordance with another embodiment of the invention;

FIGS. 3-6 illustrate schematically, in cross section, semiconductor structures formed using apparatus of the present invention;

FIG. 7 illustrates a portion of the apparatus for fabricating semiconductor structures of FIG. 1 in greater detail; and

FIG. 8 illustrates a process for forming semiconductor structures in accordance with the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 schematically illustrates a multi-chamber reactor system 100, configured to form semiconductor structures having multiple monocrystalline material layers, in accordance with an exemplary embodiment of the invention. System 100 includes a first deposition chamber 110, a second deposition chamber 120, a transfer module 130 connecting chambers 110 and 120, an optional third deposition chamber 140, and an optional transfer module 150 connecting chambers 120 and 140. As explained in greater detail below, system 100 may also optionally include various ancillary chambers 160-190 coupled to transfer modules 130 and 140 using transfer modules 200-230. Although illustrated with three deposition chambers and four ancillary chambers, those skilled in the art will appreciate that a system in accordance with the present invention may have any number greater than two deposition chambers and any number of ancillary chambers.

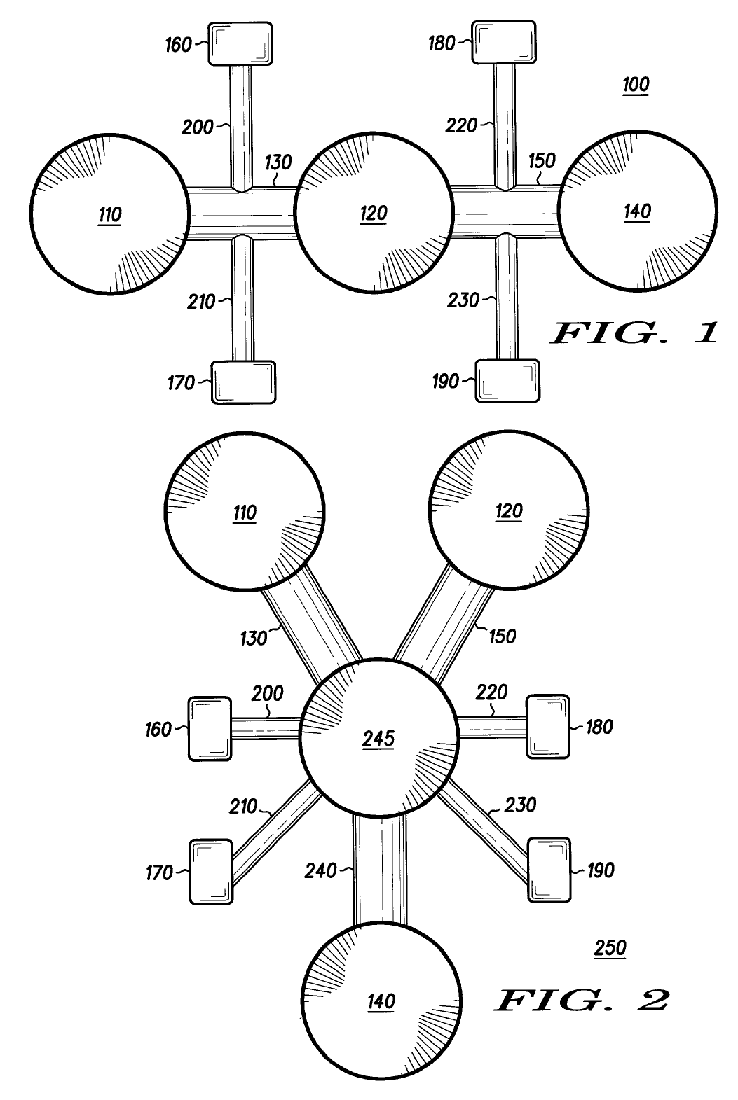

FIG. 2 illustrates a system 250 in accordance with another embodiment of the invention. System 250 is similar to system 100, except system 250 is configured as a cluster tool and includes an additional transport module 240 and a central hub 245. Similar to system 100, system 250 may include any number of ancillary chambers and any number greater than two deposition chambers.

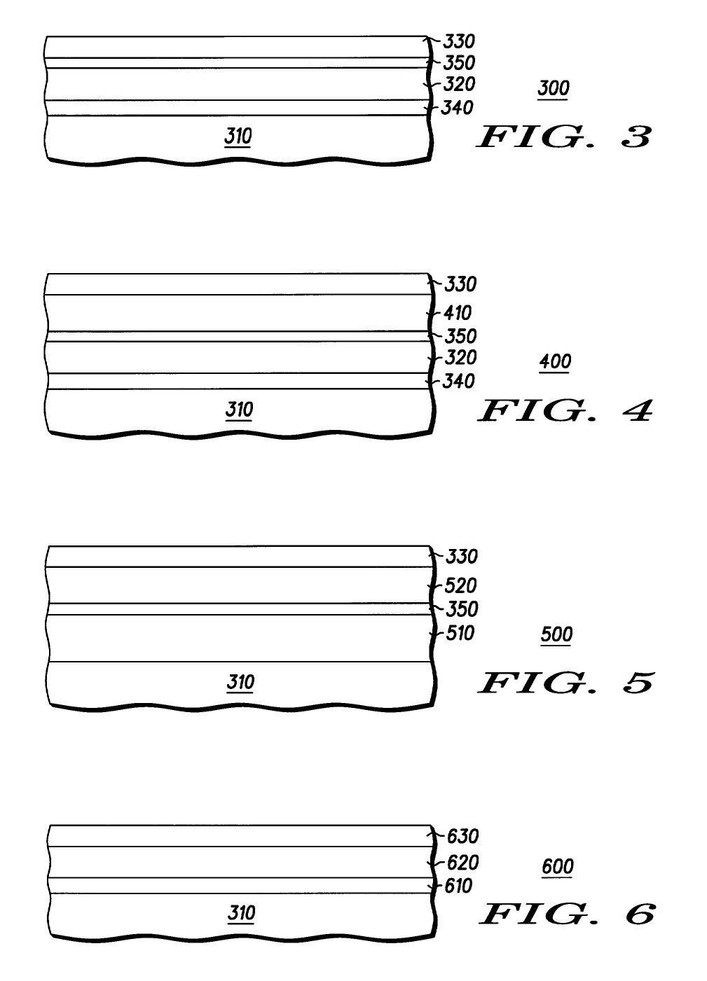

FIG. 3 schematically illustrates a semiconductor structure 300, which may be formed using a system in accordance with the present invention (e.g., system 100 or system 250). Structure 300 includes a monocrystalline substrate 310, an accommodating buffer layer 320 comprising a monocrystalline material, and a monocrystalline material layer 330. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 300 also includes an amorphous intermediate layer 340 positioned between substrate 310 and accommodating buffer layer 320. Structure 300 may also include a template layer 350 between the accommodating buffer layer and monocrystalline material layer 330 and/or a template layer (not shown) between the substrate and the accommodating buffer layer. As will be explained more fully below, the template layers help to initiate the growth of a monocrystalline material layer overlying another layer.

Substrate 310, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 310 is a wafer containing silicon or germanium, and most preferably is a high quality monocrystalline silicon wafer as used in the semiconductor industry. Accommodating buffer layer 320 is preferably a monocrystalline oxide or nitride material epitaxially grown on the underlying substrate. In accordance with one embodiment of the invention, amorphous intermediate layer 340 is grown on substrate 310 at the interface between substrate 310 and the growing accommodating buffer layer by the oxidation of substrate 310 during the growth of layer 320. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 330.

Accommodating buffer layer 320 is preferably a monocrystalline oxide, nitride, or carbide material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

Amorphous interface layer 340 is preferably an oxide formed by the oxidation of the surface of substrate 310, and more preferably is composed of a silicon oxide. The thickness of layer 340 is sufficient to relieve strain attributed to mismatches between the lattice constants of substrate 310 and accommodating buffer layer 320. Typically, layer 340 has a thickness in the range of approximately 0.5-5 nm.

The material for monocrystalline material layer 330 can be selected, as desired, for a particular structure or application. For example, the monocrystalline material of layer 330 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. Monocrystalline material layer 330 may also comprise other semiconductor materials, metals, or other materials which are used in the formation of semiconductor structures, devices and/or integrated circuits.

Appropriate materials for the template layers are discussed below. Suitable template materials chemically bond to the surface of an underlying layer at selected sites and provide sites for the nucleation of the epitaxial growth of an overlying material layer. When used, template the layers have a thickness ranging from about 1 to about 10 monolayers.

FIG. 4 illustrates, in cross section, a portion of a semiconductor structure 400 in accordance with a further embodiment of the invention. Structure 400 is similar to the previously described semiconductor structure 300, except that an additional buffer layer 410 is positioned between accommodating buffer layer 320 and monocrystalline material layer 330. Specifically, the additional buffer layer is positioned between template layer 350 and the overlying layer of monocrystalline material. The additional buffer layer, formed of, for example, a semiconductor or compound semiconductor serves to provide a lattice compensation when the lattice constant of the accommodating buffer layer cannot be adequately matched to the overlying monocrystalline semiconductor or compound semiconductor material layer.

FIG. 5 schematically illustrates, in cross section, a portion of a semiconductor structure 500 in accordance with another exemplary embodiment of the invention. Structure 500 is similar to structure 400, except that structure 500 includes an amorphous layer 510, rather than accommodating buffer layer 320 and amorphous interface layer 340, and an additional monocrystalline layer 520.

As explained in greater detail below, amorphous layer 510 may be formed by first forming an accommodating buffer layer and an amorphous interface layer in a similar manner to that described above. Monocrystalline layer 520 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 510 formed in this manner comprises materials from both the accommodating buffer and interface layers, which amorphous layers may or may not amalgamate. Formation of amorphous layer 510 between substrate 310 and monocrystalline layer 330 (subsequent to layer 520 formation) relieves stresses between layers 310 and 520 and provides a true compliant substrate for subsequent processing—e.g., monocrystalline material layer 330 formation.

The processes previously described above in connection with FIGS. 3 and 4 are adequate for growing monocrystalline material layers over a monocrystalline substrate. However, the process described in connection with FIG. 5, which includes transforming a monocrystalline accommodating buffer layer to an amorphous oxide layer, may be better for growing monocrystalline material layers because it allows any strain in layer 520 to relax.

Additional monocrystalline layer 520 may include any of the materials described throughout this application in connection with either of monocrystalline material layer 330 or additional buffer layer 410. For example, when monocrystalline material layer 330 comprises a semiconductor or compound semiconductor material, layer 520 may include monocrystalline Group IV or monocrystalline compound semiconductor materials.

In accordance with one embodiment of the present invention, additional monocrystalline layer 520 serves as an anneal cap during layer 510 formation and as a template for subsequent monocrystalline layer 330 formation. Accordingly, layer 520 is preferably thick enough to provide a suitable template for layer 330 growth (at least one monolayer) and thin enough to allow layer 520 to form as a substantially defect free monocrystalline material.

In accordance with another embodiment of the invention, additional monocrystalline layer 520 comprises monocrystalline material (e.g., a material discussed above in connection with monocrystalline layer 330) that is thick enough to form devices within layer 520. In this case, a semiconductor structure in accordance with the present invention does not include monocrystalline material layer 330. In other words, the semiconductor structure in accordance with this embodiment only includes one monocrystalline layer disposed above amorphous oxide layer 510.

The following non-limiting, illustrative examples illustrate various combinations of materials useful in structures 300, 400, and 500 in accordance with various alternative embodiments of the invention. These examples are merely illustrative, and it is not intended that the invention be limited to these illustrative examples.

### EXAMPLE 1

In accordance with one embodiment of the invention, monocrystalline substrate 310 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 320 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 330. The accommodating buffer layer can have a thickness of about 2 to about 100 nanometers (nm) and preferably has a thickness of about 5 nm. In general, it is desired to have an accommodating buffer layer thick enough to isolate the compound semiconductor layer from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 330 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 310 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700° C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. The II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 400 illustrated in FIG. 4. Substrate 310, accommodating buffer layer 320, and monocrystalline material layer 330 can be similar to those described in example 1. In addition, an additional buffer layer 410 serves to alleviate strains that might result from a mismatch of the crystal lattice of the accommodating buffer layer and the lattice of the monocrystalline material. Buffer layer 410 can be a layer of germanium (Ge) or GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 410 includes a GaAsₓP₁₋ₓ superlattice, wherein the value of x ranges from 0 to 1. In accordance with another aspect, buffer layer 410 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 410 in a like manner. The superlattice can have a thickness of about 50-500 nm and preferably has a thickness of about 100-200 nm. The template for this structure can be the same of that described in example 1. Alternatively, buffer layer 410 can be a layer of monocrystalline Ge having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 400 as illustrated in FIG. 4. Substrate material 310, accommodating buffer layer 320, monocrystalline material layer 330 and template layer 350 can be the same as those described above in example 2. In addition, additional buffer layer 410 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 410 includes InGaAs, in which the indium composition varies from 0 to about 50%. The buffer layer preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 320 and monocrystalline material layer 330.

### EXAMPLE 6

This example provides exemplary materials useful in structure 500, as illustrated in FIG. 5. Substrate material 310, template layer 350, and monocrystalline material layer 330 may be the same as those described above in connection with example 1.

Amorphous layer 510 is an amorphous oxide layer which is suitably formed of a combination of amorphous intermediate layer materials (e.g., layer 340 materials as described above) and accommodating buffer layer materials (e.g., layer 320 materials as described above). For example, amorphous layer 510 may include a combination of SiOₓ and Sr_{z}Ba_{1-z} TiO₃ (where z ranges from 0 to 1), which combine or mix, at least partially, during an anneal process to form amorphous oxide layer 510.

The thickness of amorphous layer 510 may vary from application to application and may depend on such factors as desired insulating properties of layer 510, type of monocrystalline material comprising layer 330, and the like. In accordance with one exemplary aspect of the present embodiment, layer 510 thickness is about 2 nm to about 100 nm, preferably about 2-10 nm, and more preferably about 5-6 nm.

Layer 520 comprises a monocrystalline material that can be grown epitaxially over a monocrystalline oxide material such as material used to form accommodating buffer layer 320. In accordance with one embodiment of the invention, layer 520 includes the same materials as those comprising layer 330. For example, if layer 330 includes GaAs, layer 520 also includes GaAs. However, in accordance with other embodiments of the present invention, layer 520 may include materials different from those used to form layer 330. In accordance with one exemplary embodiment of the invention, layer 520 is about 1 monolayer to about 100 nm thick.

### EXAMPLE 7

This example provides exemplary materials useful in structure 500, as illustrated in FIG. 5. This exemplary structure is similar to the structure described above, except that template layer 350 includes a surfactant. The surfactant is formed by, for example, terminating the growth of a strontium titanate accommodating buffer layer with strontium and epitaxially depositing the surfactant onto the terminated surface. The surfactant may comprise, but is not limited to, elements such as Al, In and Ga, but will be dependent upon the composition of the accommodating buffer layer and the overlying layer of monocrystalline material for optimal results. In one exemplary embodiment, Al is used for the surfactant and functions to modify the surface and surface energy of accommodating buffer layer. Preferably, surfactant is epitaxially grown, to a thickness of one to two monolayers. The surfactant is then exposed to a reactant such as arsenic, for example, to form capping layer. The surfactant may be exposed to a number of materials to create the capping layer, such as elements which include, but are not limited to, As, P, Sb and N. The surfactant and the capping layer combine to form template layer 350. The addition of the surfactant to the template layer facilitates layer-by-layer growth or Frank Van der Merle growth of subsequently grown films.

### EXAMPLE 8

FIG. 6 illustrates a semiconductor structure 600 in accordance with another embodiment of the invention. Structure 600 is similar to the previously described structures, except structure 600 includes a carbide accommodating buffer layer 610, rather than an oxide accommodating buffer layer, and a capping layer 620.

Structure 600 is formed by forming a monocrystalline oxide layer on substrate 310 with an amorphous interface layer as described herein. The capping layer and the carbide layer are then formed by depositing about 50 Å of silicon over the monocrystalline oxide layer. Rapid thermal annealing is then conducted in the presence of a carbon source such as acetylene or methane, for example, at a temperature within a range of about 800° C. to 1000° C. to form capping layer 620 and silicate amorphous layer 610. Other suitable carbon sources may be used as long as the rapid thermal annealing step functions to amorphize the monocrystalline oxide layer into a silicate amorphous layer and carbonize the top silicon layer to form capping layer 620 which in this example would be a silicon carbide (SiC) layer. Finally, a compound semiconductor layer 630, such as gallium nitride, is epitaxially grown over the SiC surface to form structure 600.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphized to form a silicate layer which adsorbs the strain between the layers. Moreover, unlike past use of a SiC substrate, this embodiment of the invention is not limited by wafer size which is usually less than 2 inches in diameter for SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

### EXAMPLE 9

The structure of this example is similar to the structure of example 6, except the template layer includes a thin layer of Zintl type phase material composed of metals and metalloids having a great deal of ionic character. In this case, template layer 350 functions as a “soft” layer with non-directional bonding but high crystallinity which absorbs stress build up between layers having lattice mismatch. Materials for template 350 may include, but are not limited to, materials containing Si, Ga, In, and Sb such as, for example, AlSr₂, (MgCaYb)Ga₂, (Ca,Sr,Eu,Yb)ln₂, BaGe₂As, and SrSn₂As₂.

As a specific example, an SrAl₂ layer may be used as template layer 350 and an appropriate monocrystalline material layer 330 and/or 520 such as GaAs is grown over the SrAl₂ layer. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer as well as on the interatomic distance. In this example, Al assumes an sp³ hybridization and can readily form bonds with monocrystalline material layer 330.

The compliant substrate produced by use of the Zintl type template layer of this embodiment can absorb a relatively large strain without a significant energy cost. In the above example, the bond strength of the Al is adjusted by changing the volume of the SrAl₂ layer, thereby making the device tunable for specific applications which include the monolithic integration of III-V and Si devices and the monolithic integration of high-k dielectric materials (e.g., for CMOS technology).

Referring again to FIGS. 1 and 2, system 100 or system 250 may be used to form the structures illustrated above in FIGS. 3-6, without exposing the substrates or structures to ambient conditions between deposition or other processing steps. In particular, the accommodating buffer layer, the amorphous interface layer, any template layers, and the monocrystalline material layers may be grown or deposited, and optional anneal and/or other processing steps may be performed, without exposing the structures to the atmosphere between processing steps. Thus, multiple high quality epitaxially layers may be formed on a substrate using a system in accordance with the present invention.

By way of example, structure 300 may be formed using system 100 by forming accommodating buffer layer 320 and amorphous oxide layer 340 in first deposition chamber 110, forming template layer 350, and forming monocrystalline material layer 330 (e.g., a GaAs layer) in second deposition chamber 120. Accommodating buffer layers and compound semiconductor layers are desirably formed in separate chambers because reactants such as oxygen used to form the accommodating buffer layer may deleteriously affect properties of subsequently formed compound semiconductor or other material layers. For example, oxygen may degrade the desired opto-electronic properties of GaAs. Furthermore, optional third deposition chamber 140 may be used to form additional layers on the semiconductor structures, such as additional monocrystalline layers, insulating layers, or conducting layers typically used in the manufacture of microelectronic devices.

Ancillary chambers 160-190 may be used for a variety of purposes in the manufacture of the semiconductor structures, and may be configured as desired for a particular application. For example, ancillary chambers may be used for metrology, formation of template layers, wafer or structure cleaning, annealing, etch processing, as load-lock chambers, and the like.

In accordance with one embodiment of the invention, chamber 110 is a molecular beam epitaxy (MBE) reactor configured to form accommodating buffer layer 320 and amorphous layer 340. However, chamber 110 may also include other forms of deposition reactors such as chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), ultrasonic jet deposition (UJD), or the like.

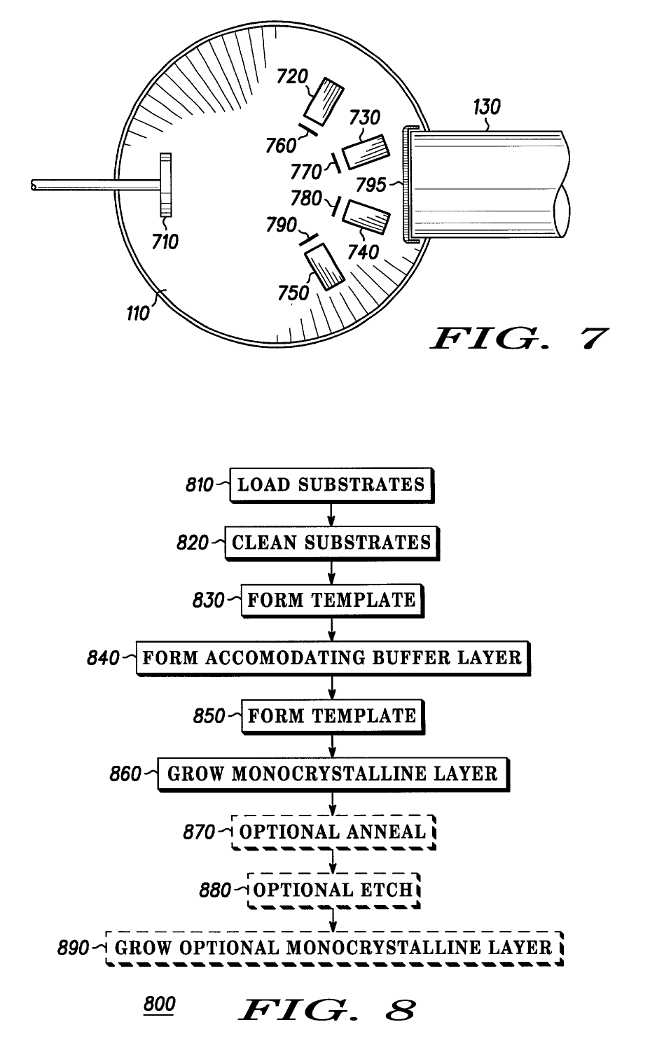

FIG. 7 illustrates an exemplary MBE chamber 110 in greater detail. Exemplary chamber 110 includes a rotating manipulator 710, effusion cells 720-740, a plasma source 750, and shutters 760-790. Chamber 110 also includes a valve mechanism 795, which is designed to seal chamber 110 during a deposition process and allow transport of the substrates (e.g. wafers) to other chambers of system 100 before or after the deposition process, allowing the wafers to be transported between chambers, without venting system 100.

Chamber 110 and manipulator 710 may be configured to handle wafers of various sizes, and in accordance with one embodiment of the invention, manipulator 710 and chamber 110 are designed to process wafers having a diameter of up to about 300 mm. Manipulator 710 is further configured to heat the wafer to a temperature up to at least about 850° C., with temperature variation over the wafer of about one-two percent. Furthermore, chamber 110 is preferably designed such that a variation of a film thickness of a deposited film is about ± two percent of the thickness and composition of the film.

Cells 720-740 include material to be used to form a desired film. In accordance with the illustrative embodiment, cell 720 includes a barium source, cell 730 includes a strontium source, and cell 740 includes a titanium source. Cells 730 and 740 are preferably designed to operate at a temperature up to about 1200° C. and the source materials are contained in pyrolytic boron nitride PBN crucibles within the cells; cell 740 is preferably designed to operate at temperatures up to about 2000° C., in which titanium is contained in a tantalum or carbide-coated graphite crucible, and oxygen is introduced into the chamber via plasma source 750, having liner comprising alumina—for example, a an electro cyclotron reactor (ECR) or a radio frequency plasma generator.

Chamber 110 may also include analytical tools such as Reflection High Energy Electron Diffraction (RHEED) to monitor the film crystal quality and composition during deposition (e.g., as the wafer rotates), a short wavelength ellispometer to determine the thickness of the growing film and/or endpoint of a template formation process, or the like.

In accordance with one aspect of this embodiment, a template layer may also be formed in chamber 110. Alternatively, a template layer, if desired, may be formed in one or more of the other chambers such as one of the ancillary chambers 160-190.

Chambers 120 and 140 may also include MBE reactors and be configured in a manner similar to chamber 110. Alternatively, chambers 120 and 140 include other forms of deposition apparatus such as evaporation reactors for depositing conductive material, CVD reactors, or the like. In accordance with one embodiment of the invention, chamber 120 is an MBE reactor configured to deposit compound semiconductor material such as GaAs to form, for example, material layer 330, illustrated in FIGS. 2-4.

As noted above, ancillary chambers 160-190 may be configured to perform a variety of processing and/or metrology functions. In accordance with one illustrative embodiment of the invention, chamber 160 is a load-lock chamber, chamber 170 is a metrology chamber, chamber 180 is a rapid thermal anneal (RTA) chamber, and chamber 190 is an etch chamber.

Load-lock chamber 160 is designed to receive wafers for processing and expose the wafers to a vacuum pressure. Chamber 160 (or, optionally, an additional chamber) may also be configured to perform a dry clean or deoxidation of the surface of the wafers. In accordance with one aspect of this embodiment, chamber 160 includes a hydrogen bake reactor or a hydrogen plasma reactor.

Metrology chamber 170 may include a variety of tools for analyzing film properties, and if desired, for forming a template for subsequent film deposition. For example, chamber 170 may include a strontium source for forming a template layer for subsequent compound semiconductor monocrystalline growth over an oxide and ultraviolet ellipsometry, ion scatter spectroscopy, or other metrology tools to measure the endpoint for the template formation.

RTA chamber is configured to heat the structures to a desired temperature to, for example, form amorphous layer 510, illustrated in FIG. 5. In accordance with one aspect of this embodiment, RTA chamber also includes gas sources to provide an overpressure of one or more of the film constituents during the anneal process. For example, if a GaAs film is exposed to the anneal process, chamber 180 includes an overpressure of As from, for example, a tertiary butyl arsenic (TBA), subliming arsenic, or arsine source.

Etch chamber 190 suitably includes a dry etch reactor such as a reactive ion etch or dry chemical etch reactor. In accordance with one aspect of this embodiment, chamber 190 is designed to remove a portion of one or more of the films deposited using system 100. For example, chamber 190 may be configured to remove a portion of monocrystalline material layer 330 to remove impurities in the film that may migrate to the top of the film during wafer processing. In accordance with one aspect of this embodiment, etch chamber 190 includes a high energy beam reactor chamber to remove a portion of a film. The energy beam may comprise ions such as argon ions, electrons, or photons, which are transmitted toward the surface of the film at a glancing angle. The incident angle is selected such that the surface damage to the film surface is mitigated. The beam flux and the surface temperature can be varied to optimize the cleaning effect.

FIG. 8 illustrates a process 800 for forming the semiconductor structures using system 100. Process 800 includes a load step 810, an optional clean step 820, an optional template formation step 830, an accommodating buffer layer formation step 840, an optional template formation step 850, a monocrystalline layer growth step 860, an optional anneal step 870, an optional etch step 880, and an optional additional monocrystalline layer growth step 890.

Load substrates step 810 includes placing substrates such as silicon wafers into system 100, e.g., into chamber 160, and sealing and evacuating chamber 160 to form a vacuum. In accordance with a preferred embodiment of the invention, the semiconductor substrate is a silicon wafer having a (100) orientation. The substrate is preferably oriented on axis or, at most, about 4° off axis toward [110]. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate.

Next, the substrates may be transferred to a clean chamber (e.g., chamber 170) to remove contaminants and/or undesired oxides from the surface of the wafers (step 820). In accordance with one aspect of this embodiment, the wafers are exposed to a hydrogen plasma clean process for about 60-300 seconds at elevated temperature.

Next, the wafers are transported to chamber 110 for optional template formation step 830 and accommodating buffer layer formation step 840. If the substrate includes an oxide layer, this layer may also be removed in chamber 110 by depositing a thin layer of strontium, barium, a combination of strontium and barium, or other alkali earth metals or combinations of alkali earth metals. In the case where strontium is used, the substrate is then heated to a temperature of about 730-800° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline accommodating buffer material.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline accommodating buffer layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters (e.g., shutters 760-790) in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered 2×1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material (step 850). For example, for the subsequent growth of a monocrystalline compound semiconductor material layer of GaAs, the MBE growth of the strontium titanate monocrystalline layer can be capped by terminating the growth with 1-2 monolayers of titanium, 1-2 monolayers of titanium-oxygen or with 1-2 monolayers of strontium-oxygen. Any of these form an appropriate template for deposition and formation of a gallium arsenide monocrystalline layer. Step 850 may be performed in chamber 110 or any of the ancillary chambers 160-190. Alternatively, template layer formation step 850 may include deposition of aluminum as described above in connection with example 7.

Following the formation of the template, the wafers are transferred to chamber 120 for monocrystalline layer formation (step 860). In accordance with one embodiment of the invention, the monocrystalline material includes GaAs and is formed by introducing arsenic into the chamber and subsequently introducing gallium to react with the arsenic to form a monocrystalline layer of GaAs. Alternatively, gallium can be deposited on the capping layer to form a Sr—O—Ga bond and subsequently introducing arsenic to form GaAs.

Structure 400, illustrated in FIG. 4, can be formed by the process discussed above with the addition of an additional buffer layer deposition step. The buffer layer is formed, using for example chamber 120, overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 500, illustrated in FIG. 5, may be formed by growing an accommodating buffer layer, forming an amorphous oxide layer over the substrate, and growing the monocrystalline material layer over the accommodating buffer layer, as described above. The accommodating buffer layer and the amorphous oxide layer are then exposed to an anneal process (step 870) sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 510. The substrate is then transferred back to chamber 120 to form layer 520 and layer 330 is then subsequently grown over layer 520.

In accordance with one aspect of this embodiment, layer 510 is formed by exposing substrate 310, the accommodating buffer layer, the amorphous oxide layer, and monocrystalline layer 520 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 510. For example, an overpressure of arsenic may be employed to mitigate degradation of a GaAs layer during step 870.

As noted above, layer 520 of structure 500 may include any materials suitable for either of layers 330 or 310. Accordingly, any deposition or growth methods described in connection with either layer 330 or 310, may be employed to form layer 520.

Optional etch step 880 may be used to remove undesired contaminants from a surface of the structure prior to further processing. Although illustrated in process 800 as occurring subsequent to anneal step 870, etch step may suitably be performed prior to step 870. In accordance with one embodiment of the invention, step 880 includes exposing layer 330 to an etch such as an argon ion etch process.

Finally, step 890 may include any additional processing steps used in the manufacture of semiconductor devices. For example, step 890 may include deposition of insulating, conducting, dielectric, or other films.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process CVD, MOCVD, MEE, ALE, PVD, CSD, PLD, UJD, or the like. Further, by a similar process, other monocrystalline accommodating buffer layers such as carbonates, alkaline earth metal titanates, zirconates, hafnates, tantalates, vanadates, ruthenates, and niobates, peroskite oxides such as alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes apparatus and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 mm in diameter and possibly at least approximately 300 mm.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A multi-chamber system for forming a semiconductor structure comprising:
a first chamber for forming a monocrystalline oxide on a silicon substrate; and
a second chamber coupled to said first chamber, said second chamber configured to form a compound semiconductor over the monocrystalline oxide.

2. The multi-chamber system of claim 1, further comprising a transfer module coupled to said first chamber and said second chamber.

3. The multi-chamber system of claim 1, further comprising an anneal chamber.

4. The multi-chamber system of claim 3, wherein said anneal chamber is a rapid thermal anneal chamber.

5. The multi-chamber system of claim 1, further comprising a metrology chamber.

6. The multi-chamber system of claim 5, wherein said metrology chamber comprises an ultraviolet ellispometer.

7. The multi-chamber system of claim 5, wherein said metrology chamber is configured to form a template layer over the monocrystalline oxide.

8. The multi-chamber system of claim 1, further comprising an etch chamber.

9. The multi-chamber system of claim 8, wherein the etch chamber includes a high energy beam reactor.

10. The multi-chamber system of claim 1, further comprising a third deposition chamber.

11. The multi-chamber system of claim 1, wherein said first chamber and said second chamber form part of a cluster tool and are coupled together via a central hub.

12. The multi-chamber system of claim 1, wherein said first chamber and said second chamber are coupled together in a linear arrangement.

13. The multi-chamber system of claim 1, wherein the second chamber is a molecular beam epitaxy reactor configured to grow monocrystalline gallium arsenide.

14. The multi-chamber system of claim 1, wherein the first chamber is configured to grow a material selected from the group consisting of alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

15. A system for forming a semiconductor structure having a monocrystalline layer, the system comprising:
a first chamber form forming a monocrystalline accommodating buffer layer;
a second chamber for forming a monocrystalline layer overlying said accommodating buffer layer; and
a sealed passageway spanning between said first chamber and said second chamber, said sealed passageway configured to allow movement of a substrate between said first chamber and said second chamber.

16. The system of claim 15, wherein the first chamber comprises a molecular beam epitaxy reactor.

17. The system of claim 15, wherein the second chamber comprises a molecular beam epitaxy reactor.

18. The system of clam 15, wherein the accommodating buffer layer is selected from the group consisting of alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, gadolinium oxide, gallium nitride, aluminum nitride, and boron nitride.

19. The system of claim 15, wherein the monocrystalline layer comprises a compound semiconductor.

20. The system of claim 19, wherein the compound semiconductor is gallium arsenide.

21. The system of claim 15, further comprising an etch chamber.

22. The system of claim 15, further comprising a metrology chamber.

23. The system of claim 15, further comprising an anneal chamber.

24. The system of claim 15, further comprising a template formation apparatus.

25. The system of claim 15, further comprising a third deposition chamber coupled to said second deposition chamber.

26. The system of claim 15, wherein said first chamber and said second chamber are coupled through a central hub.

27. A method of forming a semiconductor structure using a multi-chamber system, the method comprising the steps of:
providing a silicon substrate;
forming a monocrystalline oxide on the silicon substrate in a first chamber of the system;
moving the structure from the first chamber to a second chamber of the system; and
forming a compound semiconductor layer overlying the monocrystalline oxide in said second chamber.

28. The method of forming a semiconductor structure of claim 27, further comprising the step of forming an amorphous oxide layer between the silicon substrate and the monocrystalline oxide during the formation of the monocrystalline oxide.

29. The method of forming a semiconductor structure of claim 27, further comprising the step of annealing the monocrystalline oxide to cause the monocrystalline oxide to become amorphous.

30. The method of forming a semiconductor structure of claim 27, further comprising the step of forming a template layer between the monocrystalline oxide and the compound semiconductor layer.

31. A method of forming a semiconductor structure using a single, integrated system, the method comprising the steps of:
providing a monocrystalline substrate;
forming a monocrystalline accommodating buffer layer in a first chamber of the system; and
forming a monocrystalline material layer overlying the accommodating buffer layer in a second chamber of the system.

32. The method of forming a semiconductor structure using a single, integrated system of claim 31, further comprising annealing the structure using a third chamber of the integrated system.

33. The method of forming a semiconductor structure using a single, integrated system of claim 31, further comprising forming a template layer in a fourth chamber of the system.

34. The method of forming a semiconductor structure using a single, integrated system of claim 31, further comprising loading the monocrystalline substrates in a chamber of the system.

35. The method of forming a semiconductor structure using a single, integrated system of claim 31, further comprising etching a portion of the monocrystalline material layer in a chamber of the system.
